(19) United States
(12) Patent Application Publication
(10) Pub. No.: US 2014/0203287 A1
(43) Pub. Date: Jul. 24, 2014

(54) NITRIDE LIGHT-EMITTING DEVICE WITH CURRENT-BLOCKING MECHANISM AND METHOD FOR FABRICATING THE SAME

(71) Applicants: JIANPING ZHANG, EL MONTE, CA (US); MARIO SAENGER, EL MONTE, CA (US); WILLIAM SO, EL MONTE, CA (US); FANGHAI ZHAO, EL MONTE, CA (US); CHUNHUI YAN, EL MONTE, CA (US)

(72) Inventors: JIANPING ZHANG, EL MONTE, CA (US); MARIO SAENGER, EL MONTE, CA (US); WILLIAM SO, EL MONTE, CA (US); FANGHAI ZHAO, EL MONTE, CA (US); CHUNHUI YAN, EL MONTE, CA (US)

(73) Assignee: INVENLUX LIMITED, CENTRAL (HK)

(21) Appl. No.: 13/555,087

(22) Filed: Jul. 21, 2012

(51) Int. Cl. H01L 33/32

(52) U.S. Cl. 257/76; 438/22; 257/E33.023

(57) ABSTRACT

A nitride light emitting device comprises a current blocking Schottky junction zone formed below the p-electrode and above the active region so that current injection from the p-electrode to the area of the active region that is vertically shaded by the p-electrode is blocked by the Schottky junction zone. A method for fabricating the same is also provided.

### 1. FIELD OF THE INVENTION

The present invention relates in general to light-emitting device, particularly to nitride light-emitting device such as nitride LED with current-blocking mechanism beneath metallic electrode, and method for fabricating the same.

### 2. DESCRIPTION OF THE RELATED ART

III-nitride based light-emitting devices such as light-emitting diodes (LEDs) are widely acknowledged as the next generation light sources and are currently emerging as strong replacement of incandescent and fluorescent lamps in general lighting. For example, the field of interest uses Cerium-doped yttrium aluminum garnet (YAG:Ce) phosphor to convert InGaN multiple-quantum-well (MQW) LED's blue emission into white light, yielding commercial white light LEDs with luminous efficacies in the range of 80-130 lm/W. The R&D White LED luminous efficacy record reported so far has reached 183 lm/W (Y. Narukawa et al, J. Phys. D: Appl. Phys. 43, 354002 (2010).). Further improvement in luminous efficacy requires additional technological advances in LED's external quantum efficiency which includes in one aspect internal quantum efficiency and in another aspect light extraction efficiency improvements.

The state-of-the-art LEDs inevitably utilize metal or metallic electrodes for current injection. The active-region shaded by the electrode contributes negligibly to the light output since the electrode is very light-absorbing. This means that a portion of injected electrons and holes recombining within the electrode-shaded active-region does not contribute to light output, resulting in less external quantum efficiency of the so-formed LEDs. In the prior art, a current blocking insulation layer is inserted beneath the P-electrode to forbidden current injection into the electrode-shaded active-region zone, as disclosed in the U.S. Pat. Nos. 5,744,828, 6,121,635, and 6,417,525.

### 3. SUMMARY OF THE INVENTION

In this application, improved current-blocking mechanisms are disclosed for nitride based light emitting device such as nitride visible LEDs. A current blocking Schottky junction zone, instead of an insulation layer, is formed below the p-electrode and above the active region so that current injection from the p-electrode to the p-electrode-shaded area of the active region is blocked by the Schottky junction zone. Therefore, no insulation layer needs to be formed between the p-electrode and the area of the active region that is vertically shaded by the p-electrode.

One aspect of the present invention provides a nitride light-emitting device such as a nitride LED comprising:
an n-type layer;
a p-type layer;
an active region sandwiched between the n-type layer and the p-type layer;
a p⁺-type layer formed over the p-type layer;
a contacting layer formed over the p⁺-type layer;
a transparent current-spreading layer formed over the contacting layer; and
a p-electrode formed over the transparent current-spreading layer;
wherein a current blocking Schottky junction zone is formed below the p-electrode and above the active region in an area vertically projected down from the p-electrode and, in the current blocking Schottky junction zone, the transparent current-spreading layer is directly stacked on the p⁺-type layer and in direct contact with the p⁺-type layer, or is directly stacked on the p-type layer and in direct contact with the p-type layer, so as to form a reverse biased Schottky junction between the transparent current-spreading layer and the p⁺-type layer, or between the transparent current-spreading layer and the p-type layer.

The p-type layer can comprise a single Mg-doped p-GaN layer, or comprise in overlying sequence a Mg-doped p⁺ GaN layer, a Mg-doped p-AlGaN layer, and a Mg-doped p-GaN layer, with thicknesses being respectively 40-80 nm, 20-60 nm, and 200-300 nm, and with the Mg-doped p⁺ GaN layer being positioned closer to the active-region.

The p⁺-type layer can comprise a heavily Mg-doped p⁺-GaN layer, Mg-doping level of the heavily Mg-doped p⁺-GaN layer is in the range from 3×10²⁰ cm⁻³ to 5×10²⁰ cm⁻³, a thickness of the heavily Mg-doped p⁺-GaN layer is in the range of 8-20 nm.

The contacting layer can comprise an undoped, or heavily Si-doped with doping level from 5×10¹⁹ cm⁻³ to 3×10²⁰ cm⁻³, or heavily Mg-doped with doping level from 3×10²⁰ cm⁻³ to 5×10²⁰ cm⁻³ InGaN layer, and wherein In-composition and thickness of the InGaN layer are designed to assure that the InGaN layer is fully strained on the p⁺-type layer so as to create a piezoelectric field greater than 1.5 MV/cm, pointing to the p⁺-type layer, wherein the In-composition of the InGaN layer is from 15% to 30% and the thickness of the InGaN layer is 1-3 nm.

The transparent current-spreading layer can be made of indium tin oxide (ITO), zinc oxide, or Niobium (Nb) doped TiO₂ with free electrons more than 10²⁰ cm⁻³.

An ohmic tunneling junction zone is formed above the p-type layer in an area where the transparent current-spreading layer, contacting layer, and the p⁺-type layer are stacked with the contacting layer being sandwiched between the transparent current-spreading layer and the p⁺-type layer.

The nitride light-emitting device can further comprise an active-region preparation layer sandwiched between the active region and the n-type layer, the active-region preparation layer comprises a Si-doped GaN layer with Si doping level not higher than 5×10¹⁷ cm⁻³ and a thickness of 200-500 nm, or low-temperature GaN layer with a thickness of 50-300 nm, or a GaN/InGaN multiple layer structure.

The nitride light-emitting device can further comprise a GaN-based layer on which the n-type layer is formed, the GaN-based layer comprises a single unintentionally doped (UID) GaN layer, or a single Si-doped GaN layer, or a combination of a GaN-containing buffer layer, an unintentionally doped (UID) GaN layer, an AlGaN layer with Al-composition greater than 10%, and a Si-doped GaN layer.

The nitride light-emitting device can further comprise a substrate selected from sapphire, Si, GaN, MN, SiC, or GaAs, over which the n-type layer is formed.

The nitride light-emitting device further comprises an n-electrode, the n-electrode is formed on an upper surface of the n-type layer facing the active region, or on a lower surface of the n-type layer through a hole in the substrate exposing the lower surface of the n-type layer, wherein, when the n-electrode is formed on the lower surface of the n-type layer, the n-electrode is vertically aligned with a p-electrode formed on the transparent current-spreading layer.

Preferably, the current blocking Schottky junction zone is conformal and vertically aligned with the p-electrode and a size of lateral cross section of the current blocking Schottky junction zone is the same as that of the p-electrode.

Another aspect of the present invention provides a method for fabricating a nitride light-emitting device such as nitride LED comprising:
providing a substrate;
forming an n-type layer over the substrate;
forming an active region over the n-type layer;
forming a p-type layer over the active region;
forming a p⁺-type layer over the p-type layer;
forming a contacting layer over the p⁺-type layer;
etching the contacting layer to expose the p⁺-type layer in a predetermined area;
forming a transparent current-spreading layer over the contacting layer, wherein the transparent current-spreading layer is in direct contact with the p⁺-type layer in the predetermined area to form a current blocking Schottky junction between the transparent current-spreading layer and the p⁺-type layer; and
forming a p-electrode over the transparent current-spreading layer, the p-electrode covers an area vertically aligned with the predetermined area.

The step of etching the contacting layer may also etch a portion of the p⁺-type layer in the predetermined area, but does not expose the p-type layer.

The step of etching the contacting layer may also etch the p⁺-type layer so as to expose the p-type layer in the predetermined area, wherein the transparent current-spreading layer is in direct contact with the p-type layer in the predetermined area to form a current blocking Schottky junction between the transparent current-spreading layer and the p-type layer.

### 4. BRIEF DESCRIPTION OF THE DRAWINGS

The accompanying drawings, which are included to provide a further understanding of the invention and constitute a part of this application, illustrate embodiments of the invention and together with the description serve to explain the principle of the invention. Like reference numbers in the figures refer to like elements throughout, and a layer can refer to a group of layers associated with the same function. Throughout this disclosure, like reference number represents like part.

FIG. 1A illustrates the cross-sectional view of a nitride based visible LED according to an embodiment of the present invention.

FIG. 1B illustrates the cross-sectional perspective view of a nitride based visible LED according to the embodiment of the present invention as shown in FIG. 1A.

FIG. 2A illustrates the cross-sectional view of a nitride based visible LED according to another embodiment of the present invention.

FIG. 2B illustrates the cross-sectional perspective view of a nitride based visible LED according to the embodiment of the present invention as shown in FIG. 2A.

FIGS. 3A-3D illustrate the process steps for the fabrication of an LED according to an embodiment of the present invention.

FIG. 4 illustrates the cross-sectional view of a nitride based visible LED according to still another embodiment of the present invention.

### 5. DETAILED DESCRIPTION OF EMBODIMENTS

Throughout the specification, the term III-nitride or nitride in general refers to metal nitride with cations selecting from group IIIA of the periodic table of the elements. That is to say, III-nitride includes MN, GaN, InN and their ternary (AlGaN, InGaN, InAlN) and quaternary (AlInGaN) alloys. III-nitride or nitride can also include small portion of transition metal nitride component such as TiN, ZrN, HfN with molar fraction not larger than 10%. For example, III-nitride or nitride may include AlₓIn_{y}Ga_{z}Ti_{(1-x-y-z)}N, AlₓIn_{y}Ga_{z}Zr_{(1-x-y-z)}N, AlₓIn_{y}Ga_{z}Hf_{(1-x-y-z)}N, with (1-x-y-z)≦10%. A III-nitride layer or active-region means that the layer or active-region is made of III-nitride semiconductors.

Nitride based visible LEDs contain p-type nitride layers with pronounced resistivity (1 Ω·cm or above) because of the large acceptor activation energies (150-250 meV). As a result, the lateral current spreading distance within a p-type nitride layer is very limited (5-10 μm depending on the resistivity). The regular GaN visible LEDs are of lateral sizes of 300 μm and above. Obviously, a more conductive current spreading layer is needed for p-side in nitride based LEDs. The state-of-the-art nitride-based visible LEDs utilize a transparent current spreading layer, usually made of indium-tin-oxide (ITO), formed on a p-type nitride layer. Between the p-type nitride layer and ITO layer, an InGaN-containing interface layer is desired to facilitate the ITO/p-GaN ohmic tunneling junction formation. Further, according to the present inventors' observation, in order to have good ohmic ITO/p-GaN tunneling junction, the Mg-doping level and thickness of the interface p⁺-type layer such as p⁺-GaN layer are of significant importance.

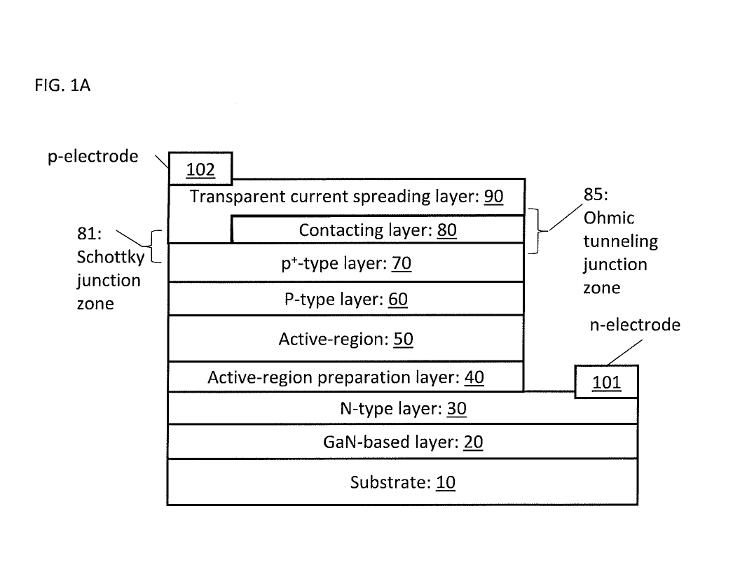

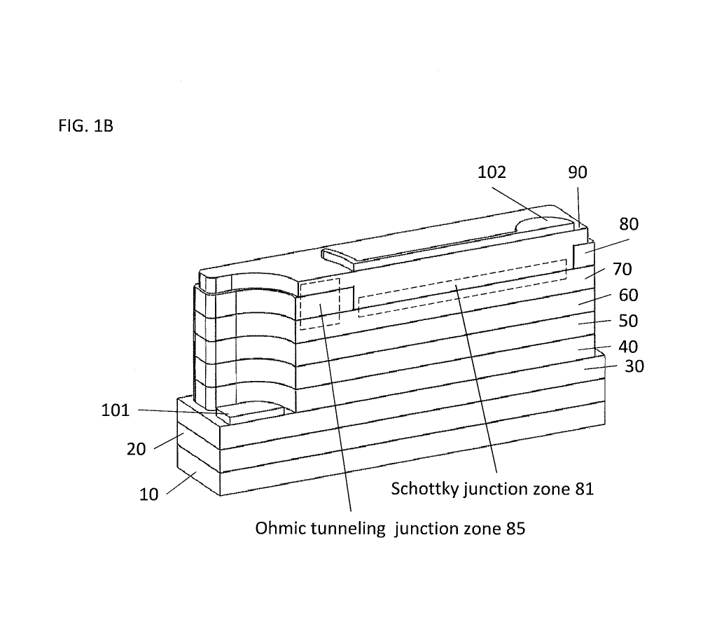

An embodiment according to the present invention is illustrated in FIG. 1A, with the cross-sectional schematic layered structure of a nitride based visible LED. Substrate 10 can be sapphire, Si, GaN, MN, SiC, GaAs and the like, which are suitable for III-nitride epitaxy. Formed over substrate 10 is a GaN-based layer 20, which can be a single GaN layer such as an unintentionally doped (UID) GaN layer or a Si-doped GaN layer, or a combination of a few GaN-containing layers such as a buffer layer, an unintentionally doped (UID) GaN layer, an AlGaN layer with Al-composition greater than 10%, and a Si-doped GaN layer. The total thickness of layer 20 can be greater than 1 μm for establishing a good crystal structure for the following layers' formation. The layer sequence and compositions, if layer 20 comprises a few GaN-containing layers, are not refrained from any combinations as long as layer 20 can achieve its purpose as establishing good crystal quality for subsequent layers' formation and possessing negligible absorption to light generated by the LED structure formed above. N-type layer 30 is a 2-5 μm-thick Si-doped GaN layer with doping level greater than 5×10¹⁸ cm⁻³. Layer 30 serves as n-current spreading layer and n-contacting layer for ohmic contact formation to n-electrode 101. Again, for n-type layer 30 to fulfill these purposes, the doping level and thickness can vary as long as layer 30 has a sheet resistance less than 30 Ω/square, optionally less than 20 Ω/square. Optionally, formed over layer 30 is an active-region preparation layer 40, which can be a 200-500 nm-thick lightly Si-doped GaN layer (for example, Si level about 5×10¹⁷ cm⁻³ or less), a 50-300 nm-thick low-temperature (formed at 700° C.-900° C.) grown GaN layer or an InGaN containing GaN/InGaN multiple layer structure. An InGaN containing active-region 50 is formed over layer 40 and can be made of a single quantum well InGaN layer, or GaN/InGaN multiple quantum well (MQW), i.e., with multiple InGaN quantum wells each separated by a GaN quantum barrier. Following the active-region 50 is an Mg-doped GaN-based p-type layer 60, which can be a single Mg-doped p-GaN layer, or contain in overlying sequence a Mg-doped p⁺ GaN layer, a Mg-doped p-AlGaN layer, and a Mg-doped p-GaN layer, with thicknesses being respectively 40-80 nm, 20-60 nm, and 200-300 nm, and with the Mg-doped p⁺ GaN layer being positioned closer to the active-region 50. Specifically, another heavily Mg-doped p⁺-type layer 70 such as heavily Mg-doped ptGaN layer is formed over p-type layer 60. The Mg-doping level in p⁺-type layer 70 is preferred to be greater than 1×10²⁰ cm⁻³, optionally in-between 3×10²⁰ cm⁻³ and 5×10²⁰ cm⁻³, with its thickness greater than 5 nm, optionally in-between 8 nm and 20 nm or 10 nm and 15 nm. On top of p⁺-type layer 70 is an InGaN-based contacting layer 80. According to an embodiment of the present invention, layer 80 can be an undoped, or heavily Si-doped (5×10¹⁹ cm⁻³ to 3×10²⁰ cm⁻³), or heavily Mg-doped (3×10²⁰ cm⁻³ to 5×10²⁰ cm⁻³) InₓGa₁₋ₓN layer with In-composition of 15% to 30% (i.e., x=0.15-0.30), optionally 25% (i.e., x=0.25). The In-composition and layer thickness of contacting layer 80 are designed to assure a fully strained InₓGa₁₋ₓ N layer growth on top of heavily Mg-doped p⁺-GaN layer 70, creating a piezoelectric field greater than 1.5 MV/cm, optionally greater than 2 MV/cm, pointing to layer 70. This requires that the InGaN based contacting layer 80 is within a thickness equal to or less than 3 nm, optionally in-between 1 nm and 2 nm. On top of contacting layer 80 is a transparent current-spreading layer (TCL) 90, which can be made of indium tin oxide (ITO), zinc oxide, Niobium (Nb) doped TiO₂ and the like. Layer 90 is transparent to the light generated by active-region 50 and with free electrons more than 10²⁰ cm⁻³. When current-spreading layer 90 directly contacts with p⁺-type layer 70, a reverse biased Schottky junction is formed therebetween. When current-spreading layer 90 directly contacts with p-type layer 60, a reverse biased Schottky junction can also be formed therebetween.

These configurations of current-spreading layer 90, contacting layer 80, and p⁺-type layer 70 ensure an ohmic tunneling junction formation within the tri-layer structure thereof (ohmic tunneling junction zone 85 formation). The proper selection of the Mg-doping level and thickness of the p⁺-type layer 70 as described above ensures to obtain sufficient electron and hole conductive ohmic tunneling junction. The lower bandgap of contacting layer 80 and the additional constructive piezoelectric field within contacting layer 80 greatly enhance the tunneling probability.

Finally, p-electrode 102, and n-electrode 101 are formed for electrical connection, respectively on current-spreading layer 90 and n-type layer 30.

Another difference between the embodiment shown in FIG. 1A and that disclosed in prior art is a Schottky junction zone 81 formed below p-electrode 102. As described previously, p-electrode shaded active-region contributes negligible to light output, and it is desirable to restrict current from flowing into the shaded active-region area. As shown in FIG. 1A, InGaN-based contacting layer 80 does not exist in the area vertically projected down from p-electrode 102. Instead of forming ohmic tunneling junction, because of the nonexistence of contacting layer 80, in the Schottky junction zone 81 where current-spreading layer 90 directly contacts with p⁺-type layer 70, a reverse biased Schottky junction is formed. This greatly reduces the current flowing into the active-region shaded by electrode 102. In areas other than zone 81, ohmic tunneling junction zone 85 is formed where layer 90, layer 80, and layer 70 coexist and vertically stacked on each other.

The formation of Schottky junction zone 81 and ohmic tunneling junction zone 85 are more straightforwardly presented in FIG. 1B (highlighted by dashed boxes), where a possible cross-sectional perspective view of the embodiment shown in FIG. 1A is illustrated.

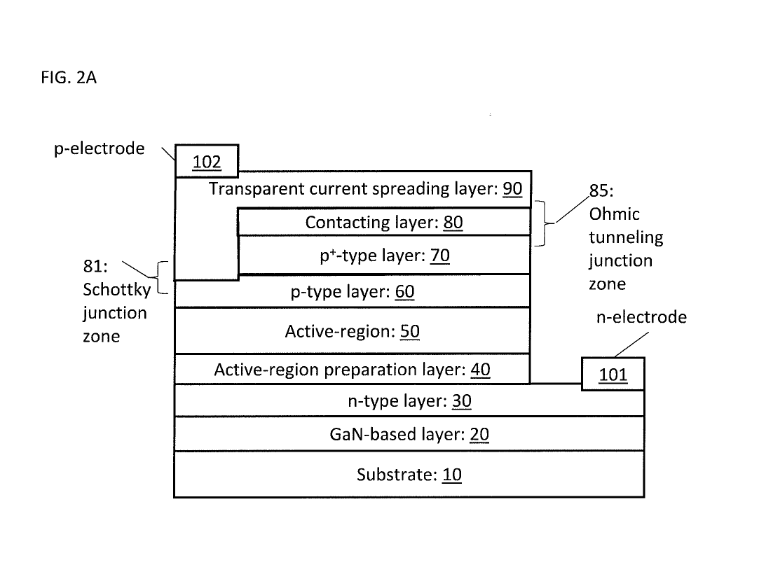

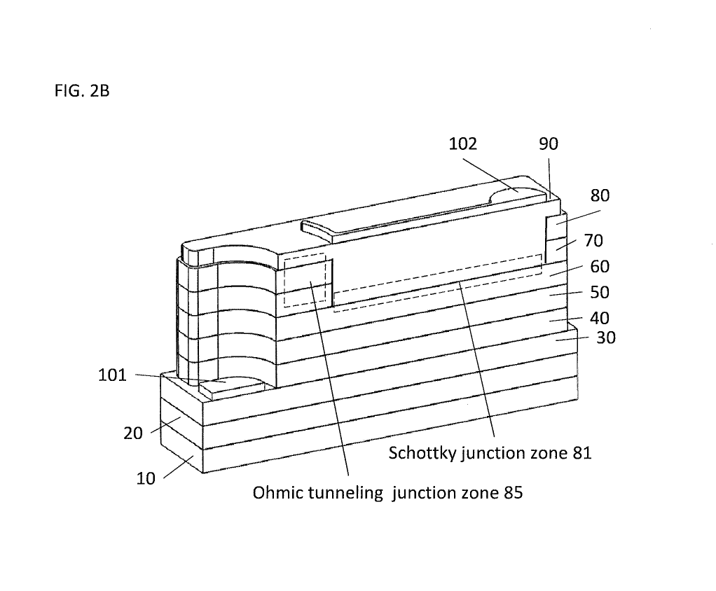

Another embodiment according to the present invention is illustrated in FIG. 2A. It differentiates from the embodiment shown in FIG. 1A in that in addition to the non-existence of InGaN-based contacting layer 80 in the area vertically projected down from the p-electrode 102, there is also no heavily Mg-doped p⁺-GaN layer 70 in the area vertically projected down from the p-electrode 102, so that current-spreading layer 90 is in direct contact with p-type layer 60 in the area vertically projected down from the p-electrode 102. And the formation of Schottky junction zone 81 and ohmic tunneling junction zone 85 are more straightforwardly presented in FIG. 2B (highlighted by dashed boxes), where a cross-sectional perspective view of the embodiment shown in FIG. 2A is illustrated.

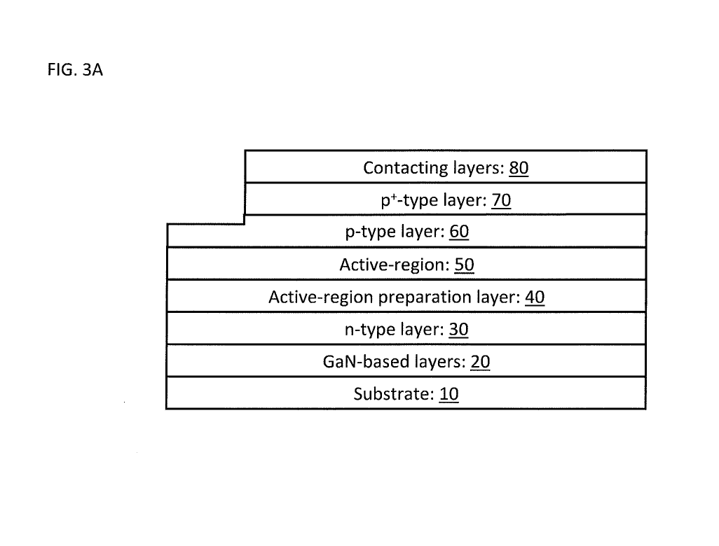

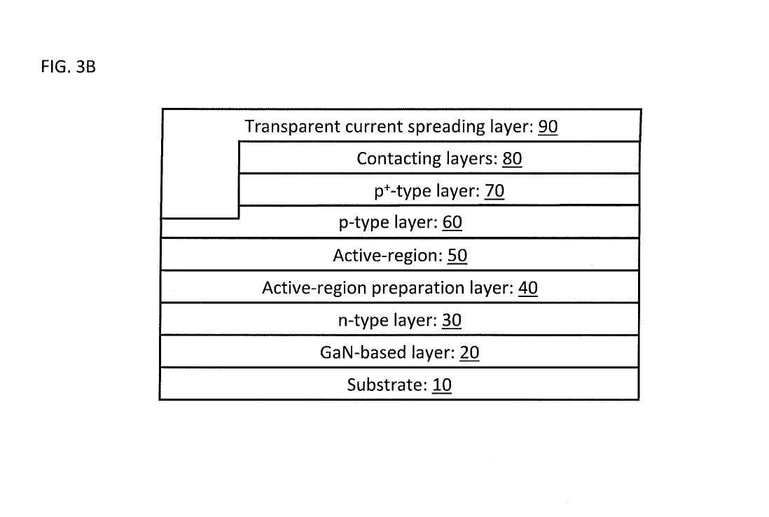

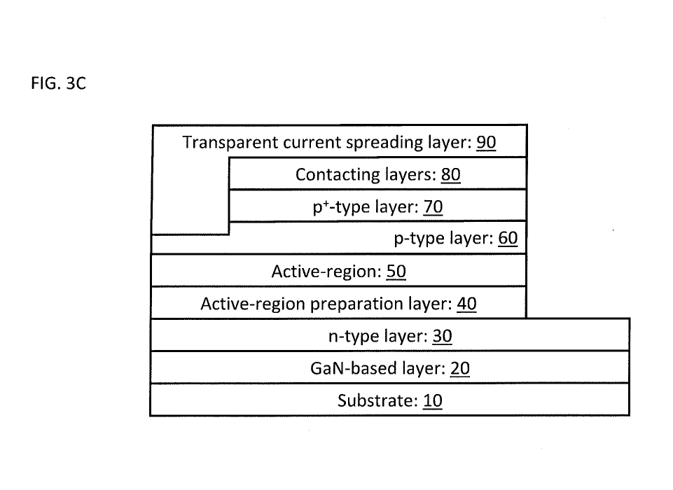

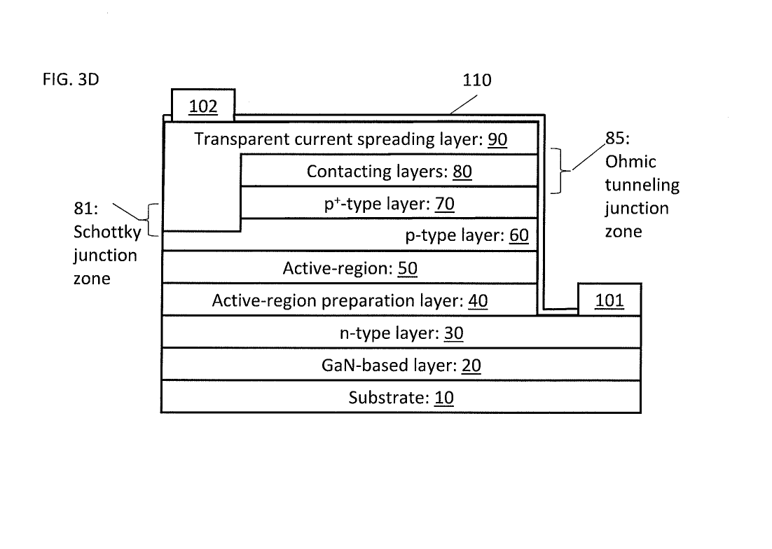

The fabrication of the embodiments can be done according to any conventional semiconductor processing method, such as the process flow shown in FIG. 3A-3D. The process can be finished using the standard nitride LED process technologies, such as lithography and dry etching. Shown in FIG. 3A is the p-mesa formation process, wherein the area for p-electrode to sit on is etched, for example, by ion-coupled plasma (ICP), to remove a portion of InGaN-based contacting layer 80 and heavily Mg-doped p⁺-GaN layer 70. As shown in FIG. 3A-3D, the etched p-mesa should be laterally big enough to accommodate the p-electrode, and vertically deep enough to remove at least InGaN-based contacting layer 80 below electrode 102, and optionally in addition, to completely remove heavily Mg-doped p⁺-GaN layer 70 below electrode 102. In an embodiment, only contacting layer 80 is removed from below electrode 102. In another embodiment, contacting layer 80 and a top portion of p⁺-type layer 70 are removed from below electrode 102. In still another embodiment, both layer 80 and layer 70 are removed from below electrode 102. In further still another embodiment, layer 80, layer 70, and a top portion of layer 60 are removed from below electrode 102. Next step is to form transparent current spreading layer 90, covering and in contact with layer 80 and the exposed p-mesa surface, which is optionally to be an exposed surface of p⁺-type layer 70 or p-type layer 60, as shown in FIG. 3A-3B. The third step (FIG. 3C) is to form n-mesa by removing a portion of layer 90, layer 80, layer 70, layer 60, active region 50, and active-region preparation layer 40, respectively, in the designated area for n-electrode, to expose a surface of n-type layer 30 for the formation of n-electrode 101. Finally, n-electrode 101 and p-electrode 102 are formed respectively on the exposed surface of n-type layer 30 of the n-mesa and the designated area on current-spreading layer 90 sitting above the exposed p-mesa surface, as shown in FIG. 3D. N- and p-electrodes can be made of metal such as Ti, Al, Au, Cr, Pt et al. Further, passivation layer 110 made of SiO₂ or silicon nitride can be deposited to cover the whole surface of the above obtained structure except for the n- and p-electrode areas (mostly the n- and p-bonding pad areas, which are the major portion of n-, and p-electrode, used for wire-bonding for electric current flowing into the LED).

Ohmic tunneling junction zone 85 is formed between current-spreading layer 90, contacting layer 80, and p⁺-type layer 70 which are stacked in sequence, and Schottky junction zone 81 is formed between current-spreading layer 90 and p⁺-type layer 70, or between current-spreading layer 90 and p-type layer 60, which are stacked and in direct contact with each other as described above. In the normal device operation mode, a positive voltage is applied to the p-electrode 102 with regard to the n-electrode 102 (forward bias condition). Under this LED forward bias condition, however, ohmic tunneling junction 85 and Schottky junction 81 are reverse biased. Current is restricted only flowing through ohmic tunneling junction zone 85 because of the ohmic tunneling effect, and virtually no current flows through the Schottky junction zone because of the reverse bias to the Schottky junction. This current-blocking mechanism distributes holes to the active-region un-shaded vertically by p-electrode, resulting in improved LED external quantum efficiency.

In the embodiments of the present invention, the Schottky junction zone 81 is formed below electrode 102 and vertically aligned with electrode 102. Preferably, the shape of the lateral cross section of Schottky junction zone 81 is conformal with that of electrode 102, and the size of the lateral cross section of Schottky junction zone 81 can be the same as that of electrode 102, or within the range of ±10%, or ±5% of that of electrode 102. Here the size of the lateral cross section of Schottky junction zone 81 being the same as that of electrode 102 means that they are the same within normal processing error in the art.

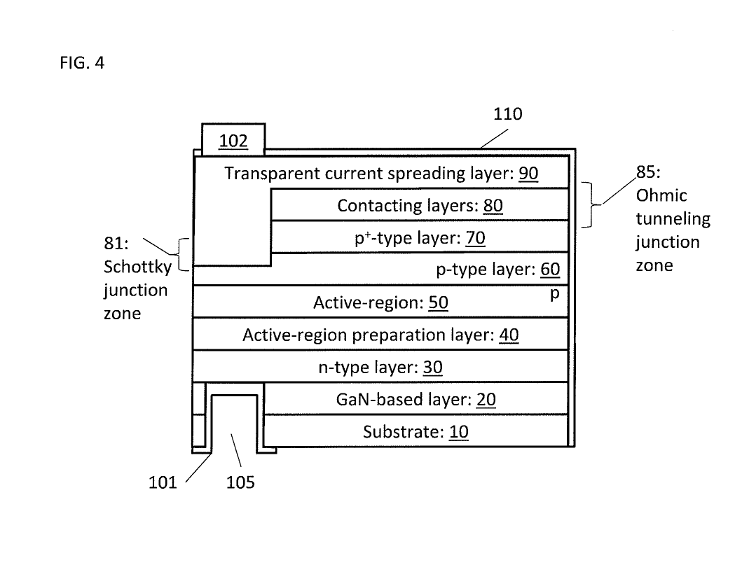

Another embodiment according to the present invention is illustrated in FIG. 4, wherein the current blocking Schottky junction zone 81 is formed below p-electrode 102 to improve device external quantum efficiency, n-electrode 101 is formed on Si-doped GaN n-contacting layer 30 from the substrate 10 side, in the area in vertical alignment with Schottky junction zone 81 and p-electrode 102. This embodiment utilizes more active-region area for light-emitting, improving light output and quantum efficiency. The fabrication of n-electrode 101, however, is more challenging, requiring the formation of hole 105 through substrate 10 and layer 20 to access layer 30 and the formation of n-electrode on the exposed surface of layer 30, sidewall of hole 105, and part of the surface area of substrate 10 surrounding hole 105. The conformal shape of n-electrode 101 can be formed via vapor phase deposition such as electron-beam deposition, and magnetron sputtering deposition, et al, optionally with additional electrochemical plating. In one embodiment, substrate 10 is made of Si or GaAs, hole 105 may be formed via dry etching or wet-chemical etching. In another embodiment, substrate 10 is made of GaN and hole 105 may be formed via laser-induced evaporation. In still another embodiment, substrate 10 is made of GaN and hole 105 may be formed via UV light assisted electrochemical anodizing. In still another embodiment, substrate 10 is made of SiC and hole 105 may be formed via UV light assisted electrochemical anodizing. Electrical and heat conductive material such as metal can be filled into hole 105 that is coated with electrode 101.

The current blocking Schottky junction zone 81 and ohmic tunneling junction zone 85 as described in the above embodiments can also be applied to other type of nitride light-emitting device, such as a vertical thin-film light-emitting device. The fabrication of vertical thin-film light-emitting device is known in the prior art. In brief, for the light-emitting structure illustrated in FIG. 1, after the transparent current-spreading layer 90 is formed over the contacting layer 80, a conductive reflector instead of p-electrode 102 is formed over the transparent current-spreading layer 90. Then the whole structure is bonded to a conductive superstrate on the conductive reflector side, and the original substrate 10 is removed by known methods such as laser lift-off, chemical etching, wafer lapping/polishing, and ion-coupled plasma (ICP) etching. Finally, another transparent current-spreading layer is formed in place of the on the substrate 10, on which a cathode contact is then formed. An anode contact is formed on the conductive reflector.

The present invention has been described using exemplary embodiments. However, it is to be understood that the scope of the present invention is not limited to the disclosed embodiments. On the contrary, it is intended to cover various modifications and similar arrangement or equivalents which can be obtained by a person skilled in the art without creative work or undue experimentation. The scope of the claims, therefore, should be accorded the broadest interpretation so as to encompass all such modifications and similar arrangements and equivalents.

1. A nitride light-emitting device comprising:
an n-type layer;
a p-type layer;
an active region sandwiched between the n-type layer and the p-type layer;
a p⁺-type layer formed over the p-type layer;
a contacting layer formed over the p⁺-type layer;
a transparent current-spreading layer formed over the contacting layer; and
a p-electrode formed over the transparent current-spreading layer;
wherein a current blocking Schottky junction zone is formed below the p-electrode and above the active region in an area vertically projected down from the p-electrode.

2. The nitride light-emitting device of claim 1, wherein the p-type layer comprises a single Mg-doped p-GaN layer, or comprises in overlying sequence a Mg-doped p⁺ GaN layer, a Mg-doped p-AlGaN layer, and a Mg-doped p-GaN layer, with thicknesses being respectively 40-80 nm, 20-60 nm, and 200-300 nm, and with the Mg-doped p⁺ GaN layer being positioned closer to the active-region.

3. The nitride light-emitting device of claim 1, wherein the p⁺-type layer comprises a heavily Mg-doped p⁺-GaN layer, Mg-doping level of the heavily Mg-doped p⁺-GaN layer is in the range from 3×10²⁰ cm⁻³ to 5×10²⁰ cm⁻³, a thickness of the heavily Mg-doped p⁺-GaN layer is in the range of 8-20 nm.

4. The nitride light-emitting device of claim 1, wherein the contacting layer comprises an undoped, or heavily Si-doped with doping level from 5×10¹⁹ cm⁻³ to 3×10²⁰ cm⁻³ or heavily Mg-doped with doping level from 3×10²⁰ cm⁻³ to 5×10²⁰ cm⁻³ InGaN layer, and wherein In-composition and thickness of the InGaN layer are designed to assure the InGaN layer is fully strained on the p⁺-type layer so as to create a piezoelectric field greater than 1.5 MV/cm, pointing to the p⁺-type layer.

5. The nitride light-emitting device of claim 4, wherein the In-composition of the InGaN layer is from 15% to 30% and the thickness of the InGaN layer is 1-3 nm.

6. The nitride light-emitting device of claim 1, wherein the transparent current-spreading layer is made of indium tin oxide (ITO), zinc oxide, or Niobium (Nb) doped TiO₂ with free electrons more than 10²⁰ cm⁻³.

7. The nitride light-emitting device of claim 1, wherein an ohmic tunneling junction zone is formed above the p-type layer in an area where the transparent current-spreading layer, contacting layer, and the p⁺-type layer are stacked with the contacting layer being sandwiched between the transparent current-spreading layer and the p⁺-type layer.

8. The nitride light-emitting device of claim 1, further comprising an active-region preparation layer sandwiched between the active region and the n-type layer, the active-region preparation layer comprises a Si-doped GaN layer with Si doping level not higher than 5×10¹⁷ cm⁻³ and a thickness of 200-500 nm, or low-temperature GaN layer with a thickness of 50-300 nm, or a GaN/InGaN multiple layer structure.

9. The nitride light-emitting device of claim 1, further comprising a GaN-based layer on which the n-type layer is formed, the GaN-based layer comprises a single unintentionally doped (UID) GaN layer, or a single Si-doped GaN layer, or a combination of a GaN-containing buffer layer, an unintentionally doped (UID) GaN layer, an AlGaN layer with Al-composition greater than 10%, and a Si-doped GaN layer.

10. The nitride light-emitting device of claim 1, further comprising a substrate selected from sapphire, Si, GaN, MN, SiC, or GaAs, over which the n-type layer is formed.

11. The nitride light-emitting device of claim 10, further comprising an n-electrode, the n-electrode is formed on an upper surface of the n-type layer facing the active region, or on a lower surface of the n-type layer through a hole in the substrate exposing the lower surface of the n-type layer.

12. The nitride light-emitting device of claim 11, wherein, when the n-electrode is formed on the lower surface of the n-type layer, the n-electrode is vertically aligned with a p-electrode formed on the transparent current-spreading layer.

13. The nitride light-emitting device of claim 1, wherein the current blocking Schottky junction zone is conformal and vertically aligned with the p-electrode and a size of lateral cross section of the current blocking Schottky junction zone is the same as that of the p-electrode.

14-16. (canceled)

17. The nitride light-emitting device of claim 1, wherein, in the current blocking Schottky junction zone, the transparent current-spreading layer is directly stacked on the p-type layer and in direct contact with the p-type layer, so as to form a reverse biased Schottky junction between the transparent current-spreading layer and the p-type layer.

18. The nitride light-emitting device of claim 1, wherein, in the current blocking Schottky junction zone, the transparent current-spreading layer is directly stacked on the p⁺-type layer and in direct contact with the p⁺-type layer, so as to form a reverse biased Schottky junction between the transparent current-spreading layer and the p⁺-type layer.
